(19) United States
(12) Patent Application Publication
(10) Pub. No.: US 2026/0158949 A1
(43) Pub. Date: Jun. 11, 2026

(54) Charging Pile, and Control Method for Charging Pile

(71) Applicant: Autel Digital Power Co., Ltd., Shenzhen (CN)

(72) Inventor: Huan ZHANG, Shenzhen (CN)

(73) Assignee: Autel Digital Power Co., Ltd., Shenzhen, GD (CN)

(21) Appl. No.: 18/706,001

(22) PCT Filed: Nov. 1, 2022
(86) PCT No.: PCT/CN2022/129050

§ 371 Date: Apr. 30, 2024

(30) Foreign Application Priority Data
Nov. 5, 2021 (CN) 202111305691.2

(51) Int. Cl. B60L 53/302; B60L 53/31; H05K 7/20

(52) U.S. Cl. CPC B60L 53/302; B60L 53/31; H05K 7/20154; H05K 7/20172; H05K 7/20209; H05K 7/20909; H05K 7/20945

(57) ABSTRACT

A charging pile includes a first housing and a second housing, the first housing defines a first air channel in an annular shape, the first housing includes a heat dissipation housing and a heat exchange housing arranged along the circumference of the first air channel, and a power module of the charging pile is provided in the heat dissipation housing. The second housing defines a second air channel, and the second housing is configured to allow external air to enter and be exported from the second air channel. The second housing is in contact with the heat exchange housing.

The present application claims priority to the Chinese patent application No. 202111305691.2 entitled “Charging Pile, and Control Method for Charging Pile” filed on Nov. 5, 2021, to the China National Intellectual Property Administration, the entire contents of which are incorporated herein by reference.

### TECHNICAL FIELD

The present application relates to the technical field of electric power devices, and in particular to a charging pile and a control method for a charging pile.

### BACKGROUND OF THE INVENTION

A direct current charging pile is a kind of electrical integrated device for fast charging of electric automobiles, which inputs three-phase dynamic electricity and finally charges an electric vehicle through an internal AC-DC system. The internal power module is the core component of the system, and is also the largest heat source of the device. To achieve the normal operation of the device, it needs to dissipate the heat in time. At the same time, as an electrical product that can be used outdoors, the charging pile must meet a certain level of protection.

At present, the dissipation modes of charging piles are mostly air-cooling, and the forms of air channels include multiple forms such as side air inlet and lower air inlet. Most of them use the direct ventilation mode, that is to introduce fresh ambient air into the system to cool the module. Therefore, the internal temperature, humidity and pollutants are greatly affected by the external environment.

In order to reduce the influence of fresh air as much as possible, there are three main types of solutions at present. 1. The scheme of waterproof structure design of air inlet and air outlet plus direct ventilation of filter screen is adopted; 2. air conditioning refrigeration is adopted; 3. water cooling to dissipate heat is adopted. The first scheme filters only dust and does not filter water vapor and micro-contaminants and is frequently maintained and very noisy. The second scheme has high energy consumption, high cost, and a bulky volume; the third scheme is bulky in volume and costly, and has the risk of leakage. The overall situation is that the first scheme is the most popular one; the second scheme and the third scheme are minority schemes due to the cost, the reliability, and other factors, and cannot achieve a good balance among heat dissipation, protection, energy consumption, and cost.

### SUMMARY OF THE INVENTION

The technical problem to be mainly solved by the embodiments of the present invention is to provide a charging pile and a control method for a charging pile, which can have a good heat dissipation effect while having a high protection level, a good noise reduction effect, and a low cost.

In order to solve the above technical problem, one technical scheme adopted by the present invention is: providing a charging pile, wherein the charging pile comprises a first housing and a second housing, the first housing defines a first air channel in an annular shape, the first housing comprises a heat dissipation housing and a heat exchange housing arranged along the circumference of the first air channel, and a power module of the charging pile is provided in the heat dissipation housing. The second housing defines a second air channel, and the second housing is configured to allow external air to enter and be exported from the second air channel. The second housing is in contact with the heat exchange housing. In this embodiment, the heat generated by the power module in the first housing circulates in the first air channel, and the second housing allows an external air flow with a lower temperature than that in the first air channel to pass through; since the second housing is in contact with the heat exchange housing of the first housing, the air flow with higher temperature in the first air channel can perform heat exchange and cooling with the second housing in the heat exchange housing; the air flow with a reduced temperature is guided to the power module and then cools the power module. In this embodiment, on the one hand, since the first housing is relatively closed, and it does not need to directly exchange heat with the external air flow, particulate matter or fibrous matter such as dust in the external air will not enter the first housing. Therefore, there is no need to add a filter screen and like apparatuses, so that the noise during the flow of the air flow is greatly reduced. On the other hand, since the second housing is provided to introduce fresh air for heat exchange with the heat exchange housing, the heat dissipation requirement of the charging pile is also ensured. That is, the charging pile in the present embodiment can improve the heat dissipation effect while having a good noise reduction effect.

In a further embodiment, the heat exchange housing comprises multiple first hollow plates, each of the first hollow plates is arranged at intervals, and each of the first hollow plates is provided with a first air inlet and a first air outlet in communication with an inner cavity of the first hollow plate; the heat dissipation housing is provided with a second air inlet and a second air outlet, each of the first air inlets is in communication with the second air outlet, and each of the first air outlets is in communication with the second air inlet. In this embodiment, the heat exchange housing comprises multiple hollow plates, so that the heat exchange area of the heat exchange housing is increased and the heat exchange efficiency is improved.

In a further embodiment, each first air inlet is located on the same side of the heat exchange housing; and/or each first air outlet is located on the same side of the heat exchange housing. In this embodiment, when each of the first air inlets is located on the same side and/or each of the first air outlets is located on the same side, it is possible to facilitate the introduction and/or exportation of the air flow into and/or from the heat exchange housing at the same time, thereby simplifying the structure of the heat exchange housing.

In a further embodiment, in each first hollow plate, the first air inlet and the first air outlet are both provided on the same plate element, and the first air inlet and the first air outlet are provided on two opposite ends of the plate element; each plate element is located on the same side of the heat dissipation housing; the thickness direction of the first hollow plate is a first direction; each first air inlet is arranged along the first direction, and each first air outlet is arranged along the first direction. In this embodiment, each of the first air inlets and each of the first air outlets is located on the same side, so that the structure of the heat exchange housing is simpler and the introduction and exportation of the air flow are also facilitated.

In a further embodiment, each of the first hollow plates is a rectangular hollow plate, and each of the first hollow plates comprises two first rectangular heat exchange plates arranged at intervals and four first strip-shaped plates, wherein the four first strip-shaped plates are arranged around the two first rectangular heat exchange plates, and the first rectangular heat exchange plates of two adjacent first hollow plates are arranged at intervals. In this embodiment, the rectangular hollow plate has a simple structure and low cost.

In a further embodiment, the first air inlet and the first air outlet are respectively provided on the same first strip-shaped plate, and along a length direction of the first strip-shaped plate, the first air outlet and the first air inlet are respectively located at two ends of the first strip-shaped plate. In this embodiment, each of the first air inlets and each of the first air outlets is located on the same side, so that the structure of the heat exchange housing is simpler and the introduction and exportation of the air flow are also facilitated.

In a further embodiment, the second air channel comprises a gap between each of the adjacent first hollow plates. In this embodiment, the gap between each of the first hollow plates of the heat dissipation housing is directly used as the second air channel, that is, the opposite plate bodies between two adjacent first hollow plates are both a part of the heat dissipation housing and a part of the second housing. In this way, It can simplify the structure of the charging pile, reduce the number of parts, and reduce the material cost. Meanwhile, since the external air flow is separated from the hot air in the heat exchange housing by only a block of plate element, the heat exchange efficiency is significantly improved.

In a further embodiment, the second housing comprises multiple second hollow plates, each of the second hollow plates and each of the first hollow plates are arranged in a one-by-one staggered stack way, and each of the second hollow plates comprises a third air inlet and a third air outlet in communication with the inner cavity of the second hollow plate. In the present embodiment, since multiple second hollow plates are provided, the position designs of the third air inlet and the third air outlet are made more flexible, and the introduction of the external air flow is facilitated.

In a further embodiment, each third air inlet is located on the same side of the second housing; and/or each third air outlet is located on the same side of the second housing. In this embodiment, the location of the third air inlet and/or the third air outlet on the same side can facilitate the introduction and/or exportation of external air flow into/from the second housing.

In a further embodiment, each of the third air inlets is located on the same side of the second housing, each of the third air outlets is located on the same side of the second housing, and in each of the second hollow plates, the third air inlet and the third air outlet are located on two opposite sides of the second hollow plate. In this embodiment, the third air inlet and the third air outlet being located on two opposite sides of the second hollow plate can make it more convenient for gas convection and improve heat exchange efficiency.

In a further embodiment, each of the second hollow plates comprises two second rectangular heat exchange plates arranged at intervals and four second strip-shaped plates arranged around the two second rectangular heat exchange plates, and in each of the second hollow plates, the third air inlet is arranged on one of the second strip-shaped plates, and the third air outlet is arranged on the other second strip-shaped plate on the opposite. In this embodiment, the third air outlet and the fourth air outlet are arranged opposite to each other, so that the heat exchange is more sufficient and the heat exchange efficiency is improved.

In a further embodiment, the heat exchange housing and the second housing combine to form a heat exchange module, wherein each of the first air outlets and each of the first air inlets is provided on the first side of the heat exchange module, each of the third air inlets is provided on a second side of the heat exchange module, each of the third air outlets is provided on a third side of the heat exchange module, two sides are arranged opposite to the third side, and the first side is respectively adjacent to the second side and the third side. In this embodiment, the structural arrangement between the heat exchange housing and the heat dissipation housing is more convenient.

In a further embodiment, each of the first air inlets is provided at an end portion near the second side, each of the first air outlets is provided at an end portion near the third side, each of the third air inlets is provided on the third side, and each of the third air outlets is provided on the second side. In this embodiment, the flow direction of the air flow in the first air channel is opposite to the flow direction of the air flow in the second air channel, so that the heat exchange efficiency is higher.

In a further embodiment, the charging pile further comprises a third housing sleeved on the heat exchange module, wherein the third housing is provided with a first opening communicating with each of the first air inlets, a second opening communicating with each of the first air outlets, a third opening communicating with each of the third air inlets, and a fourth opening communicating with each of the third air outlets. In this embodiment, the third housing can provide good protection for the heat exchange module.

In a further embodiment, the heat dissipation housing is connected to the third housing, and the heat dissipation housing is located on the first side of the heat exchange module. In this embodiment, the overall structure of the charging pile is more compact, and is also easier to process and assemble.

In a further embodiment, the heat dissipation housing defines a first chamber, which communicates with each first air inlet, a second chamber for accommodating the power module, and a third chamber, which communicates with each first air outlet. The first chamber, the second chamber, and the third chamber are arranged along the circumference of the first air channel. In this embodiment, the air flow in the first air channel can be made to completely pass through the power module such that the heat dissipation effect is better.

In a further embodiment, the charging pile further comprises: a first driving apparatus connected to the first housing for generating a driving force for circulating an air flow in the first air channel; and/or, a second driving apparatus connected to the second housing for generating a driving force for letting an external air flow enter and be exported from the second air channel. In this embodiment, the use of two sets of driving apparatuses enables the charging pile to have both a noise reduction mode and an efficient heat dissipation mode.

In a further embodiment, the charging pile further comprises: a first driving apparatus provided in the first housing for generating a driving force for circulating an air flow in the first air channel; and/or, a second driving apparatus provided outside the second housing and connected to the second housing for generating a driving force for letting an external air flow enter and be exported from the second air channel. In the present embodiment, when the first driving apparatus is provided in the first housing, the closure of the first housing is improved; when the second driving apparatus is provided outside the second housing, the air guide volume can be improved and the heat exchange effect can be improved.

The second aspect of the present invention also provides a control method for a charging pile, wherein the charging pile comprises a first housing, a second housing, a first driving apparatus, and a second driving apparatus, the first housing defines a first air channel in an annular shape, the first housing comprises a heat dissipation housing and a heat exchange housing arranged along a circumference of the first air channel, and a power module of the charging pile is provided in the heat dissipation housing; the second housing defines a second air channel, and the second housing is configured to enable an external air to enter and be exported from the second air channel; wherein, the second housing is in contact with the heat exchange housing; the control method includes: acquiring an operation mode of the charging pile; wherein the operation mode comprises a noise reduction mode; and when the operation mode is the noise reduction mode, controlling the first driving apparatus to turn on. In the present embodiment, the second driving apparatus is not turned on, and only the first driving apparatus drives the internal air flow of the first housing to circulate, so that the noise can be reduced and the operation of the charging pile can be quieter.

In a further embodiment, the operation mode further comprises a heat dissipation mode. After acquiring the operation mode of the charging pile, the control method further comprises: when the operation mode is the heat dissipation mode, controlling the first driving apparatus and the second driving apparatus to turn on at the same time In the present embodiment, the first driving apparatus and the second driving apparatus are simultaneously turned on when in the heat dissipation mode so that it is possible to have an excellent heat dissipation effect while having less noise than the existing charging pile.

According to the charging pile provided by the present invention, the heat generated by the power module in the first housing circulates in the first air channel, and the second housing allows an external air flow with a lower temperature than that in the first air channel to pass through; since the second housing is in contact with the heat exchange housing of the first housing, the air flow with higher temperature in the first air channel can perform heat exchange and cooling with the second housing in the heat exchange housing; the air flow with a reduced temperature is guided to the power module and then cools the power module. In this embodiment, on the one hand, since the first housing is relatively closed, and there is no need to directly exchange heat with the external air flow, particulate matter or fiber such as dust in the external air does not enter the first housing. Therefore, there is no need to add a filter screen or like apparatuses, so that the noise during the flow of the air flow is reduced, making it have a good noise reduction effect. The degree of the encapsulation of the power module is higher, so the overall protection level of the device is also higher. On the other hand, since the second housing is provided to introduce fresh air and exchange heat with the heat exchange housing, the heat dissipation requirement of the charging pile is also ensured and the cost is lower than that of a liquid cooling apparatus. That is, the charging pile in this embodiment can have a good heat dissipation effect while having high protection level, good noise reduction effect, and low cost.

### BRIEF DESCRIPTION OF DRAWINGS

In order to more clearly explain the technical scheme of the embodiments of the present application, the following will briefly introduce the drawings that need to be used in the embodiments of the present application. It is obvious that the drawings described below are only some embodiments of the present application. For those of ordinary skills in the art, other drawings can also be obtained according to the accompanying drawings without creative efforts.

FIG. 1 is a schematic perspective view of a charging pile provided by a kind of embodiment of the present invention; wherein a top plate element is removed to show the internal structure of the charging pile;

FIG. 2 is a schematic perspective view of a charging pile provided by a kind of embodiment of the present invention; wherein a top plate element and a heat exchange module are removed to show the air flow direction in the first air channel and the second air channel;

FIG. 3 is a schematic perspective view of a heat exchange module provided by a kind of embodiment of the present invention;

FIG. 4 is a schematic explosive view of a heat exchange module provided by a kind of embodiment of the present invention;

FIG. 5 is a schematic view of a first side view of a heat exchange module provided by a kind of embodiment of the present invention;

FIG. 6 is a schematic view of a second side view of a heat exchange module provided by a kind of embodiment of the present invention;

FIG. 7 is a schematic view of a complete section of a single first hollow plate and a single second hollow plate in a heat exchange module provided by a kind of embodiment of the present invention;

FIG. 8 is a flowchart of a charging pile control method provided by a kind of embodiment of the present invention;

FIG. 9 is a flowchart of a charging pile control method provided by another kind of embodiment of the present invention.

### DETAILED DESCRIPTION OF THE INVENTION

In order to make the present invention readily understood, a more particular description of the invention will be rendered by reference to accompanying drawings and specific embodiments. It needs to be noted that when an element is referred to as being “secured” to another element, it can be directly on another element or one or more intervening elements may be present in between. When one element is referred to as being “connected” to another element, it can be directly connected to another element or one or more intervening elements may be present in between. The terms “vertical”, “horizontal”, “left”, “right”, and the like are used herein for descriptive purposes only.

Unless defined otherwise, all technical and scientific terms used herein have the same meaning as commonly understood by one of ordinary skill in the art to which this invention belongs. The terminology used herein in the description of the present invention is for the purpose of describing particular embodiments only and is not to be limiting of the present invention. As used herein, the term “and/or” includes any and all combinations of one or more of the associated listed items.

In the relevant art, in order to cool a charging pile, one means is to directly introduce an external air flow into the charging pile, and the same conducts heat exchange with a power module in the charging pile and then is exported out of the charging pile. In order to prevent foreign matter or fine dust outside the charging pile from entering the charging pile, a filter screen is provided at the air inlet of the charging pile. After the filter screen is provided, the air flow entering the charging pile generates a loud noise when flowing through the filter screen. In another cooling mode, water cooling is performed directly inside the charging pile to dissipate heat. Although the noise is relatively small, the cost is high. That is, in the related art, it is difficult to effectively balance noise reduction, cost reduction, and heat dissipation with respect to the heat dissipation of a charging pile.

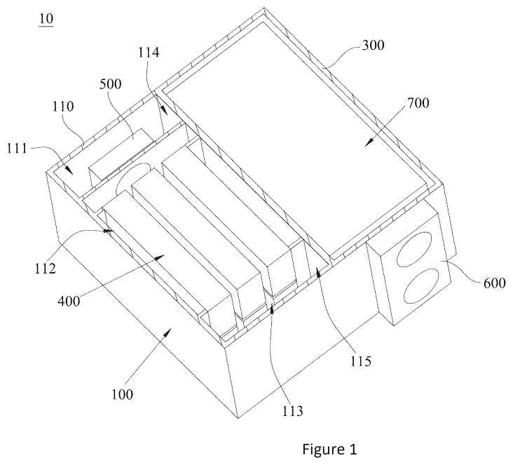

In view of this, with reference to FIGS. 1-4, the present embodiment provides a charging pile 10 that can have a good heat dissipation effect while being relatively low in cost and low in noise. Specifically, the charging pile 10 includes a first housing 100 and a second housing 200.

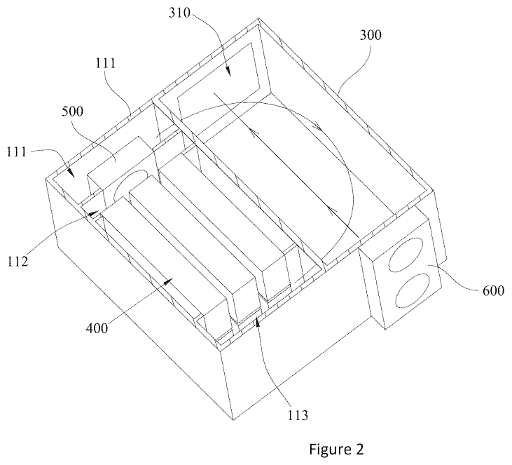

The first housing 100 defines a first air channel having an annular shape, which may have a circular annular, an annular rectangular, or other annular shapes. In this embodiment, referring to FIG. 2, the first air channel has a substantially annular rectangular shape. The first housing 100 may be integrally formed or may be spliced by multiple split housings. In the present embodiment, the first housing 100 comprises a heat dissipation housing 110 and a heat exchange housing 120 which are arranged along the circumference of the first air channel, that is to say, when the air flow in the first air channel flows, the air flow can first pass through the heat dissipation housing 110 and then enter the heat exchange housing 120; the air flow can also pass through the heat exchange housing 120 first and then the heat dissipation housing 110. The heat dissipation housing 110 and the heat exchange housing 120 each define a space of a certain section of the first air channel.

It needs to be noted that the first housing 100 may be composed of only the heat dissipation housing 110 and the heat exchange housing 120, and the first housing 100 may further include other housings in addition to the heat dissipation housing 110 and the heat exchange housing 120. In other words, the inner cavity of the heat dissipation housing 110 and the inner cavity of the heat exchange housing 120 may constitute the whole of the first air channel, or the inner cavity of the heat dissipation housing 110 and the inner cavity of the heat exchange housing 120 may constitute a part of the first air channel.

The power module 400 of the charging pile 10 is arranged in the heat dissipation housing 110, the power module 400 radiates heat in the heat dissipation housing 110, and the high-temperature air flow after heat exchange can exchange heat with the outside at the position of the heat exchange housing 120, thereby cooling the high-temperature air flow to a low-temperature air flow with a relatively low temperature.

The second housing 200 defines a second air channel, and the second housing 200 is configured to make the external air enter and export the second air channel, i.e. the external air can pass through the second air channel. The second housing 200 is in contact with the heat exchange housing 120. When the air flow in the second air channel flows through the heat exchange housing 120, the overall temperature of the heat exchange housing 120 rises. Since the heat exchange housing 120 is in contact with the second housing 200, the heat exchange housing 120 transfers heat to the second housing 200, the second housing 200 transfers heat to the low-temperature air flow passing through the second air channel, and the low-temperature air flow in the second air channel conducts heat out of the second housing 200. In other words, the low-temperature air flow passing through the second air channel can cool the high-temperature air flow in the heat exchange housing 120, and thus cool the power module 400.

In summary, according to the charging pile 10 provided in the present invention, the heat generated by the power module 400 in the first housing 100 circulates in the first air channel, and the second housing 200 allows an external air flow with a lower temperature than that in the first air channel to pass through; since the second housing 200 is in contact with the heat exchange housing 120 of the first housing 100, the air flow with higher temperature in the first air channel can perform heat exchange and cooling with the second housing 200 in the heat exchange housing 120; the air flow with a reduced temperature is guided to the power module 400 and then cools the power module 400. In this embodiment, on the one hand, since the first housing 100 is relatively closed, and there is no need to directly exchange heat with the external air flow, particulate matter or fiber such as dust in the external air does not enter the first housing 100. Therefore, there is no need to add a filter screen or like apparatuses, so that the noise during the flow of the air flow is reduced, making it have a good noise reduction effect. The degree of the encapsulation of the power module is higher, so the overall protection level of the device is also higher. On the other hand, since the second housing 200 is provided to introduce fresh air and exchange heat with the heat exchange housing 120, the heat dissipation requirement of the charging pile 10 is also ensured and the cost is lower than that of a liquid cooling apparatus. That is, the charging pile 10 according to the present embodiment can have a good heat dissipation effect while having a good noise reduction effect and a low cost.

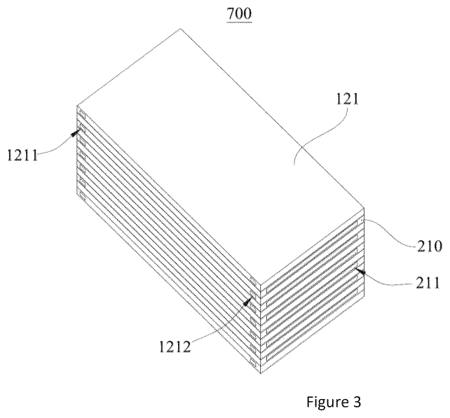

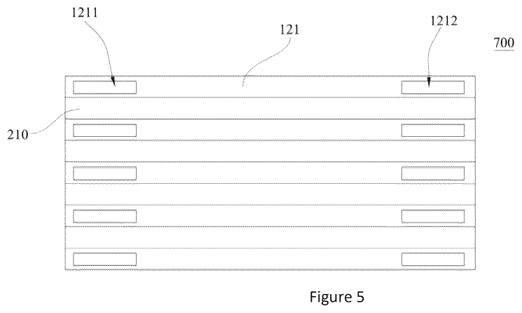

The shape of the heat exchange housing 120 and the contact position with the second housing 200 may depend on specific requirements. In this embodiment, with reference to FIGS. 3-5, the heat exchange housing 120 may comprise multiple first hollow plates 121. Each first hollow plate 121 is arranged at intervals, and each first hollow plate 121 is provided with a first air inlet 1211 and a first air outlet 1212 in communication with the inner cavity of the first hollow plate 121. The heat dissipation housing 110 is provided with a second air inlet 115 and a second air outlet 114, wherein each first air inlet 1211 is in communication with the second air outlet 114, and each first air outlet 1212 is in communication with the second air inlet 115. In other words, the air flow after exchanging heat with the power module 400 may sequentially pass through the second air outlet 114 and the first air inlet 1211 and then enter the inner cavity of the first hollow plate 121, and then sequentially pass through the first air outlet 1212 and the second air inlet 115 and then enter the heat dissipation housing 110. In particular, in the present embodiment, the number of the first hollow plates 121 is multiple, so that the air flow in the heat dissipation housing 110 is divided into multiple streams. Each stream of air flow enters the inner cavity of one of the first hollow plates 121, and then the air flows in each of the first hollow plates 121 converge at the position of the second air inlet 115 and enter the heat dissipation housing 110. In the present embodiment, since the heat exchange housing 120 is provided to be multiple plate-like structures, the surface area for heat exchange with the outside is increased, thereby improving the efficiency of heat exchange.

The manner of communication between the first air inlet 1211 and the second air outlet 114 may depend on actual needs. In one embodiment, an air duct may be provided with one end communicating with the first air inlet 1211 and the other end communicating with the second air outlet 114. The scheme of using an air duct to communicate the first air inlet 1211 and the second air outlet 114 enables each first air inlet 1211 to effectively acquire the hot air exported from the second air outlet 114 regardless of the arrangement position. In another embodiment, the first hollow plate 121 may be attached to the heat dissipation housing 110 with the first air inlet 1211 directly facing the second air outlet 114. Likewise, the manner of communication between the second air inlet 115 and the first air outlet 1212 may depend on actual needs. In one embodiment, an air duct may be provided, wherein one end of the air duct communicates with the second air inlet 115 and the other end communicates with the first air outlet 1212. The scheme of using an air duct to communicate the second air inlet 115 and the first air outlet 1212 enables each first air outlet 1212 to effectively acquire the hot air exported from the first air outlet 1212 regardless of the arrangement position. In another embodiment, the first hollow plate 121 may be attached to the heat dissipation housing 110 with the second air inlet 115 directly facing the first air outlet 1212.

Each first hollow plate 121 may be of the same shape, structure, and size or different shapes, structures, and sizes. The shapes, sizes, and arrangement positions of the first air outlet 1212 and the first air inlet 1211 on each of the first hollow plates 121 may be the same or different. In one embodiment, the shape and size of each first hollow plate 121 is the same for ease of machining. When the shape and size of each first hollow plate 121 are the same, the placement position of each first hollow plate 121 determines the placement positions of the first air inlet 1211 and the first air outlet 1212.

To facilitate the introduction of air flow into each first hollow plate 121, in one embodiment, each first air inlet 1211 may be located on the same side of the heat exchange housing 120. To facilitate the air flow to be exported from each first hollow plate 121, in one embodiment, each first air outlet 1212 is located on the same side of the heat exchange housing 120. In order to facilitate both the introduction of air flow into the first hollow plate 121 and the exportation of air flow from the first hollow plate 121, in one embodiment, each first air inlet 1211 is located on the same side of the heat exchange housing 120, while each first air outlet 1212 is located on the same side of the heat exchange housing 120. When each first air inlet 1211 is located on the same side and the first air outlet 1212 is located on the same side, the structure of the heat exchange housing 120 can be simplified and the processing cost can be reduced.

When each first air inlet 1211 is located on the same side and each first air outlet 1212 is located on the same side, the first air inlet 1211 may be located on the same side with or on a different side from the first air outlet 1212. In a further embodiment, and referring to FIGS., 3-5, all of the first air inlets 1211 and all of the first air outlets 1212 are located on the same side. Such a structure may facilitate the assembly between the heat exchange housing 120 and the heat dissipation housing 110. When all the first air inlets 1211 and the first air outlets 1212 are located on the same side of the heat exchange housing 120, specifically, in each first hollow plate 121, the first air inlets 1211 and the first air outlets 1212 are both provided on the same plate element, and the first air inlets 1211 and the first air outlets 1212 are provided on two opposite ends of the plate element. Each of the plate elements is located on the same side of the heat dissipation housing 110, the thickness direction of the first hollow plate 121 is a first direction, each first air inlet 1211 is arranged along the first direction, and each first air outlet 1212 is arranged along the first direction. In other words, each first air inlet 1211 is collectively arranged at one end of one of the plate elements of the heat exchange housing 120, and each first air outlet 1212 is collectively arranged at the other end of the plate element of the heat exchange housing 120.

The specific shape of the first hollow plate 121 can be determined according to actual requirements. With reference to FIGS. 3-5, in a kind of embodiment, each of the first hollow plates 121 is a rectangular hollow plate, and each of the first hollow plates 121 comprises two first rectangular heat exchange plates 1213 arranged at intervals and four first strip-shaped plates. The four first strip-shaped plates are arranged around the two first rectangular heat exchange plates 1213, and the first rectangular heat exchange plates 1213 of two adjacent first hollow plates 121 are arranged at intervals, and the first rectangular heat exchange plate 1213 is used for being in contact with the second housing 200. In this embodiment, the rectangular hollow plate has a simple structure and low cost.

When the first air inlet 1211 and the first air outlet 1212 are both provided on the same plate element, specifically, the first air inlet 1211 and the first air outlet 1212 are respectively provided on the same first strip-shaped plate, and along the length direction of the first strip-shaped plate, the first air outlet 1212 and the first air inlet 1211 are respectively located at two ends of the first strip-shaped plate. In this embodiment, each of the first air inlets 1211 and each of the first air outlets 1212 is located on the same side, so that the structure of the heat exchange housing 120 is simpler and the introduction and exportation of the air flow are also facilitated.

In a kind of embodiment, referring to FIGS. 3-5, the second air channel includes a gap between adjacent first hollow plates 121, and an external air flow can pass through the gap between the first hollow plates 121 to remove heat from the first hollow plate 121. In this embodiment, the gap between each of the first hollow plates 121 of the heat dissipation housing 110 is directly used as the second air channel, that is, the opposite plate bodies (i.e. the first rectangular heat exchange plates 1213) between two adjacent first hollow plates 121 are both a part of the heat dissipation housing 110 and a part of the second housing 200. In other words, the first rectangular heat exchange plate 1213 is divided into two conjoined plate elements in the thickness direction, and the plate element close to the first air channel belongs to the first housing 100, and the plate element close to the second air channel belongs to the second housing 200. The second housing 200 in the present embodiment can simplify the structure of the charging pile 10, reduce the number of parts, and reduce the material cost. Meanwhile, since the external air flow is separated from the hot air in the heat exchange housing 120 by only a block of plate element, the heat exchange efficiency is significantly improved. Of course, in order to define the complete second air channel, the second housing 200 may further include a baffle connecting the side edges of each of the first hollow plates 121 for enhancing the degree of closure of the second air channel.

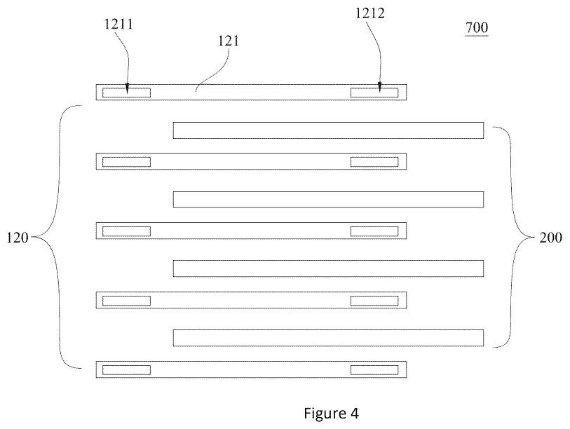

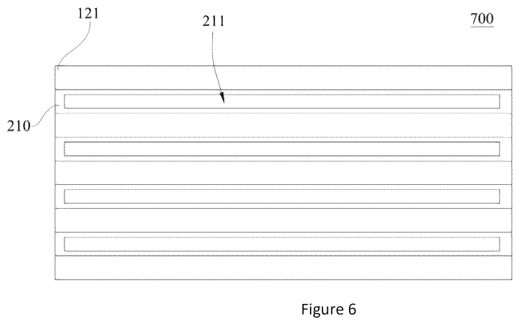

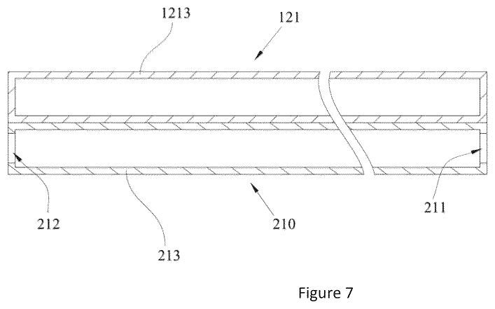

In the foregoing embodiment, the second housing 200 utilizes a partial structure of the first housing 100 to define the second air channel. In another kind of embodiment, referring to FIGS. 4-7, the second housing 200 individually defines the second air channel. Specifically, the second housing 200 includes multiple second hollow plates 210, each of the second hollow plates 210 being arranged one by one in a staggered stack with each of the first hollow plates 121. Each of the second hollow plates 210 comprises a third air inlet 211 and a third air outlet 212 communicating with the inner cavity of the second hollow plate 210. In this embodiment, since multiple second hollow plates 210 are provided, the shape structure of the second air channel can be more freely provided without being influenced by the structure of the first hollow plate 121.

In a further embodiment, each third air inlet 211 of the second housing 200 is located on the same side of the second housing 200; and/or each third air outlet 212 is located on the same side of the second housing 200. The location of the third air inlet 211 and/or the third air outlet 212 on the same side can facilitate the introduction and/or exportation of external air flow into/from the second housing 200. When the third air inlet 211 is located on the same side of the second housing 200 and the third air outlet 212 is located on the same side of the second housing 200, the third air inlet 211 and the third air outlet 212 may be located on the same side or different sides of the second housing 200. In the present embodiment, with reference to FIGS. 4-7, each third air inlet 211 is located on the same side of the second housing 200, and each third air outlet 212 is located on the same side of the second housing 200; in each second hollow plate 210, the third air inlet 211 and the third air outlet 212 are located on two opposite sides of the second hollow plate 210 (namely, the third air inlet 211 and the third air outlet 212 are located on two different sides of the second housing 200 and are oppositely provided). The structures of the third air inlet 211 and the third air outlet 212 located on two opposite sides of the second hollow plate 210 can make it more convenient for gas convection and improve heat exchange efficiency.

The specific shape of the first hollow plate 121 may depend on the actual requirements. Referring to FIGS. 3-7, in a kind of embodiment, each second hollow plate 210 comprises two spaced second rectangular heat exchange plates 213 and four second strip-shaped plates arranged around two second rectangular heat exchange plates 213. The second rectangular heat exchange plate 213 is used for contacting the first rectangular heat exchange plate 1213. In each of the second hollow plates 210, a third air inlet 211 is provided on one second strip-shaped plate, and a third air outlet 212 is provided on the other second strip-shaped plate on the opposite.

When the heat exchange housing 120 comprises multiple first hollow plates 121, the second housing 200 comprises multiple second hollow plates 210, and each first hollow plate 121 and each second hollow plate 210 are arranged in a one-by-one staggered stack. The heat exchange housing 120 and the second housing 200 can be combined to form a heat exchange module 700. In the heat exchange module 700, each first air outlet 1212 and each first air inlet 1211 are provided on the first side of the heat exchange module 700; each third air inlet 211 is provided on the second side of the heat exchange module 700; each third air outlet 212 is provided on a third side of the heat exchange module 700; the second side of the heat exchange module 700 is arranged opposite to the third side of the heat exchange module 700; the first side of the heat exchange module 700 is respectively adjacent to the second side of the heat exchange module 700 and the third side of the heat exchange module 700. In a further embodiment, each first air inlet 1211 is provided at an end portion proximate to the second side of the heat exchange module 700, each first air outlet 1212 is provided at an end portion proximate to the third side of the heat exchange module 700, each third air inlet 211 is provided at the third side of the heat exchange module 700, and each third air outlet 212 is provided at the second side of the heat exchange module 700. In this embodiment, the flow direction of the air flow in the first air channel is opposite to the flow direction of the air flow in the second air channel, so that the heat exchange efficiency is higher.

When the heat exchange housing 120 and the second housing 200 are combined to form the heat exchange module 700, in order to provide good protection for the heat exchange module 700, in a kind of embodiment, the charging pile 10 further comprises a third housing 300, and the third housing 300 is sleeved on the heat exchange module 700. The third housing 300 is provided with a first opening communicating with each of the first air inlets 1211, a second opening communicating with each of the first air outlets 1212, a third opening communicating with each of the third air inlets 211, and a fourth opening communicating with each of the third air outlets 212. The first opening is used for communicating the first air inlet 1211 with the second air outlet 114, the second opening is used for communicating the first air outlet 1212 with the second air inlet 115, and the third opening and the fourth opening are used for the external air flow to be introduced into and exported from the second housing 200.

When the third housing 300 is provided outside the heat exchange module 700, in a kind of embodiment, the heat dissipation housing 110 is connected to the third housing 300, and the heat dissipation housing 110 is located on the first side of the heat exchange module 700. In this embodiment, the overall structure of the charging pile 10 is more compact, and is also easier to process and assemble.

In a further embodiment, the heat dissipation housing 110 defines a first chamber 111, which communicates with each first air inlet 1211, a second chamber 112 for accommodating the power module 400, and a third chamber 113, which communicates with each first air outlet 1212. The first chamber 111, the second chamber 112, and the third chamber 113 are arranged along the circumference of the first air channel. In this embodiment, the air flow in the first air channel can be made to completely pass through the power module 400 such that the heat dissipation effect is better.

In order to achieve the driving of the air flow in the first air channel, the charging pile 10 further includes a first driving apparatus 500 connected to the first housing 100 for generating a driving force for circulating the air flow in the first air channel. In order to achieve the driving of the air flow in the second air channel, in a kind of embodiment, the charging pile 10 further comprises a second driving apparatus 600 connected to the second housing 200 for generating a driving force for letting an external air flow introduce into and export from the second air channel. In this embodiment, the use of two sets of driving apparatuses enables the charging pile 10 to have both a noise reduction mode and an efficient heat dissipation mode.

Further, when the charging pile 10 includes the first driving apparatus 500, the first driving apparatus 500 may be provided inside the first housing 100 or may be provided outside the first housing 100. When it is provided outside the first housing 100, an opening may be formed in the first housing 100 so that the driving force generated by the first driving apparatus 500 is transmitted into the first housing 100. Similarly, when the charging pile 10 includes the second driving apparatus 600, the second driving apparatus 600 may be provided inside the second housing 200 or may be provided outside the second housing 200. When the second driving apparatus 600 is provided outside the second housing 200, it may be provided at the position of the third air inlet 211 of the second housing 200 or at the position of the third air outlet 212 of the second housing 200.

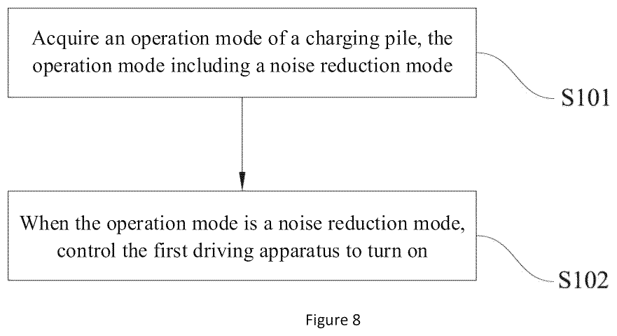

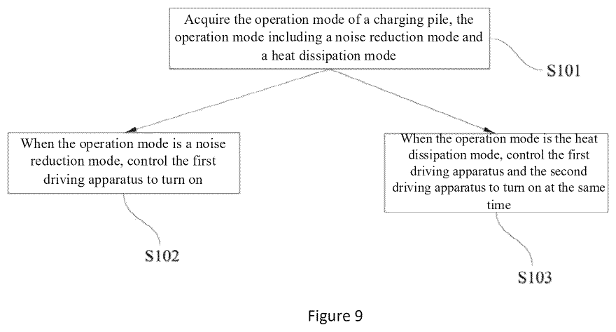

Referring to FIGS. 8-9, the second aspect of the present invention also provides a control method for the charging pile 10. The charging pile 10 comprises a first housing 100, a second housing 200, a first driving apparatus 500, and a second driving apparatus 600, wherein the first housing 100 defines a first air channel having an annular shape, the first housing 100 comprises a heat dissipation housing 110 and a heat exchange housing 120 arranged along the circumference of the first air channel, and the power module 400 of the charging pile 10 is provided in the heat dissipation housing 110. The second housing 200 defines a second air channel, and the second housing 200 is configured to allow external air to enter and be exported from the second air channel. The second housing 200 is in contact with the heat exchange housing 120.

With reference to FIG. 8, specifically, the control method comprises the following steps:
S101: acquiring an operation mode of the charging pile 10; wherein the operation mode comprises a noise reduction mode;
and S102: when the operation mode is the noise reduction mode, controlling the first driving apparatus 500 to turn on.

In the control method of the present embodiment, the second driving apparatus 600 is not turned on, and only the first driving apparatus 500 drives the internal air flow of the first housing 100 to circulate, so that the noise can be reduced and the operation of the charging pile 10 can be quieter.

Referring to FIG. 9, in a further embodiment, the operation mode further comprises a heat dissipation mode. After acquiring the operation mode of the charging pile 10, the control method further comprises:
S103: when the operation mode is the heat dissipation mode, controlling the first driving apparatus 500 and the second driving apparatus 600 to turn on at the same time.

In the present embodiment, the first driving apparatus 500 and the second driving apparatus 600 are simultaneously turned on when in the heat dissipation mode so that it is possible to have an excellent heat dissipation effect while having less noise than the existing charging pile 10.

In summary, the control method for the charging pile 10 in the present embodiment has two operating modes, namely, a noise reduction mode and a heat dissipation mode. When the charging pile 10 finds that the temperature at the position of the power module 400 is low, heat dissipation is performed in the noise reduction mode, and only the first driving apparatus 500 is turned on at this time. When it is found that the temperature at the position of the power module 400 is high, heat dissipation is performed in a heat dissipation mode. At this time, the first driving apparatus 500 and the second driving apparatus 600 are simultaneously turned on, which can improve the heat dissipation capacity and also have a good noise reduction effect.

It needs to be noted that the description of the present invention and the accompanying drawings set forth preferred embodiments of the present invention. However, the present invention can be implemented in many different forms, not limited to the embodiments described in the description. These embodiments are not used as additional restrictions on the contents of the invention. The purpose of providing these embodiments is to make a more thorough and comprehensive understanding of the disclosure of the invention. Furthermore, the above-mentioned technical features are continuously combined with each other to form various embodiments which are not listed above, and all are considered to be within the scope of the description of the present invention. Further, for those of ordinary skills in the art, improvements or transformations can be made according to the above description, and all these improvements and transformations shall belong to the protection scope of the appended claims of the invention.

1. A charging pile, comprising:
a first housing defining a first air channel having an annular shape, wherein the first housing comprises a heat dissipation housing and a heat exchange housing arranged along a circumference of the first air channel, and a power module of the charging pile is provided in the heat dissipation housing; and
a second housing defining a second air channel, the second housing being configured to enable external air to enter and be exported from the second air channel;
wherein the second housing is in contact with the heat exchange housing.

2. The charging pile according to claim 1, wherein
the heat exchange housing comprises multiple first hollow plates, the first hollow plates are arranged at intervals, and each of the first hollow plates is provided with a first air inlet and a first air outlet in communication with an inner cavity of the first hollow plate; the heat dissipation housing is provided with a second air inlet and a second air outlet, each of the first air inlets is in communication with the second air outlet, and each of the first air outlets is in communication with the second air inlet.

3. The charging pile according to claim 2, wherein
each of the first air inlets is located on a same side of the heat exchange housing; and/or,
each of the first air outlets is located on the same side of the heat exchange housing.

4. The charging pile according to claim 3, wherein
in each of the first hollow plates, the first air inlet and the first air outlet are both provided on a same plate element, and the first air inlet and the first air outlet are provided at two opposite ends of the plate element; and
each of the plate elements is located on the same side of the heat dissipation housing, a thickness direction of the first hollow plate is a first direction, each of the first air inlets is arranged along the first direction, and each of the first air outlets is arranged along the first direction.

5. The charging pile according to claim 4, wherein
each of the first hollow plates is a rectangular hollow plate, and each of the first hollow plates comprises two first rectangular heat exchange plates arranged at intervals and four first strip-shaped plates, wherein the four first strip-shaped plates are arranged around the two first rectangular heat exchange plates, and the first rectangular heat exchange plates of two adjacent first hollow plates are arranged at intervals.

6. The charging pile according to claim 5, wherein
in each of the first hollow plates, the first air inlet and the first air outlet are respectively provided on the same first strip-shaped plate, and along a length direction of the first strip-shaped plate, the first air outlet and the first air inlet are respectively located at two ends of the first strip-shaped plate.

7. The charging pile according to claim 2, wherein
the second air channel comprises a gap between each of the adjacent first hollow plates.

8. The charging pile according to claim 2, wherein
the second housing comprises multiple second hollow plates, each of the second hollow plates and each of the first hollow plates are arranged in a one-by-one staggered stack way, and each of the second hollow plates comprises a third air inlet and a third air outlet in communication with the inner cavity of the second hollow plate.

9. The charging pile according to claim 8, wherein
each of the third air inlets is located on the same side of the second housing; and/or,
each of the third air outlets is located on the same side of the second housing.

10. The charging pile according to claim 8, wherein
each of the third air inlets is located on the same side of the second housing, each of the third air outlets is located on the same side of the second housing, and in each of the second hollow plates, the third air inlet and the third air outlet are located on two opposite sides of the second hollow plate.

11. The charging pile according to claim 8, wherein
each of the second hollow plates comprises two second rectangular heat exchange plates arranged at intervals and four second strip-shaped plates arranged around the two second rectangular heat exchange plates, and in each of the second hollow plates, the third air inlet is arranged on one of the second strip-shaped plates, and the third air outlet is arranged on the other second strip-shaped plate on the opposite.

12. The charging pile according to claim 8, wherein
the heat exchange housing and the second housing combine to form a heat exchange module, wherein each of the first air outlets and each of the first air inlets is provided on a first side of the heat exchange module, each of the third air inlets is provided on a second side of the heat exchange module, each of the third air outlets is provided on a third side of the heat exchange module, the second side is arranged opposite to the third side, and the first side is respectively adjacent to the second side and the third side.

13. The charging pile according to claim 12, characterized in that wherein
each of the first air inlets is provided at an end portion near the second side, each of the first air outlets is provided at an end portion near the third side, each of the third air inlets is provided on the third side, and each of the third air outlets is provided on the second side.

14. The charging pile according to claim 12, wherein
the charging pile further comprises a third housing sleeved on the heat exchange module, wherein the third housing is provided with a first opening communicating with each of the first air inlets, a second opening communicating with each of the first air outlets, a third opening communicating with each of the third air inlets, and a fourth opening communicating with each of the third air outlets.

15. The charging pile according to claim 14, wherein
the heat dissipation housing is connected to the third housing, and the heat dissipation housing is located on the first side.

16. The charging pile according to claim 2, wherein
the heat dissipation housing defines a first chamber, a second chamber, and a third chamber arranged along the circumference of the first air channel, the first chamber being in communication with each of the first air inlets, the second chamber being used for accommodating the power module, and the third chamber being in communication with each of the first air outlets.

17. The charging pile according to claim 1, further comprising:
a first driving apparatus connected to the first housing for generating a driving force for circulating an air flow in the first air channel; and/or,
a second driving apparatus connected to the second housing for generating a driving force for letting an external air flow enter and be exported from the second air channel.

18. The charging pile according to claim 1, further comprising:
a first driving apparatus provided in the first housing for generating a driving force for circulating an air flow in the first air channel; and/or,
a second driving apparatus provided outside the second housing and connected to the second housing for generating a driving force for letting an external air flow enter and be exported from the second air channel.

19. A control method for a charging pile, wherein the charging pile comprises a first housing, a second housing, a first driving apparatus, and a second driving apparatus, the first housing defines a first air channel in an annular shape, the first housing comprises a heat dissipation housing and a heat exchange housing arranged along a circumference of the first air channel, and a power module of the charging pile is provided in the heat dissipation housing; the second housing defines a second air channel, and the second housing is configured to enable an external air to enter and be exported from the second air channel; wherein, the second housing is in contact with the heat exchange housing; wherein the control method comprises:
acquiring an operation mode of the charging pile; wherein the operation mode comprises a noise reduction mode; and
when the operation mode is the noise reduction mode, controlling the first driving apparatus to turn on.

20. The control method according to claim 19, wherein the operation mode further comprises a heat dissipation mode, and after acquiring the operation mode of the charging pile, the control method further comprises:
when the operation mode is the heat dissipation mode, controlling the first driving apparatus and the second driving apparatus to turn on at the same time.
